(19) United States
(12) Patent Application Publication
(10) Pub. No.: US 2014/0354655 A1
(43) Pub. Date: Dec. 4, 2014

(54) REDUCING FLOATING NODE LEAKAGE CURRENT WITH A FEEDBACK TRANSISTOR

(71) Applicant: QUALCOMM MEMS Technologies, Inc., San Diego, CA (US)

(72) Inventors: Cheonhong Kim, San Diego, CA (US); John Hyunchul Hong, San Clemente, CA (US); Seung-tak Ryu, Daejeon (KR)

(21) Appl. No.: 13/909,839

(22) Filed: Jun. 4, 2013

(51) Int. Cl. G06T 1/20; H03K 17/16

(52) U.S. Cl. CPC G06T 1/20; H03K 17/165
USPC 345/501; 327/108; 327/535

(57) ABSTRACT

This disclosure provides circuits and methods for reducing sub-threshold leakage currents discharging floating nodes. In one aspect, feedback from a floating node is provided to a feedback transistor configured to bias other nodes such that leakage through turned-off transistors is reduced. Additionally, leakage contributing to static power consumption may also be reduced.

### TECHNICAL FIELD

This disclosure relates to electromechanical systems and devices. More specifically, the disclosure relates to reducing leakage currents in circuits for electromechanical systems and devices.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

In some implementations, the IMOD display elements may be arranged in an array such as a two-dimensional grid and addressed by circuits associated with the rows and columns of the array. Row driver circuits may drive the gates of transistor switches that select a particular row to be addressed, and common driver circuits may provide a bias to a given row of display elements that may be synchronously updated with a row refresh.

### SUMMARY

The systems, methods and devices of this disclosure each have several innovative aspects, no single one of which is solely responsible for the desirable attributes disclosed herein.

One innovative aspect of the subject matter described in this disclosure can be implemented in a circuit with an input switch including a first switch and a second switch. A first terminal of the first switch may be coupled to receive an input signal. A first terminal of the second switch may be coupled with the first switch to provide a “feedback” node. An output switch may include a third switch. A control terminal of the third switch may be coupled to another terminal of the second switch to define a “charge” node. A feedback switch may have an output coupled to the feedback node and a control terminal coupled to the charge node. Accordingly, the feedback switch may be configured to charge the feedback node in response to a voltage level at the charge node.

In some implementations, the circuit can include a fourth switch coupled to the charge node and a first power supply. The circuit may also include a fifth switch coupled to a second power supply. The fifth switch may also be coupled to the fourth switch to provide an output node.

In some implementations, the circuit can include a third power supply provided to the feedback switch.

Another innovative aspect of the subject matter described in this disclosure can be implemented in a method for reducing leakage by charging and floating an internal node. Feedback may also be provided from the node to a feedback switch and biasing a feedback node coupled to the feedback switch.

In some implementations, feedback from the internal node may also be provided to another switch coupled to a first power supply. Another internal node may then be biased to a voltage level associated with the first power supply. Two output nodes may also be biased. The first output node may be biased to a first voltage level associated with the first power supply and the second output node may be biased to a second voltage level associated with a second power supply.

In some implementations, the voltage level of the first power supply may be lower than the voltage level of the second power supply.

Another innovative aspect of the subject matter described in this disclosure can be implemented in a circuit for reducing leakage. The circuit may charge and float an internal node. Feedback may also be provided from the node to a feedback switch. Moreover, the circuit may bias a feedback node using feedback switch.

In some implementations, the feedback switch may be configured to bias the feedback node responsive to a voltage level at the internal node.

In some implementations, another switch may charge the internal node to the voltage level.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays, organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIG. 3 is a graph illustrating movable reflective layer position versus applied voltage for an IMOD display element.

FIG. 4 is a table illustrating various states of an IMOD display element when various common and segment voltages are applied.

FIG. 5A is an illustration of a frame of display data in a three element by three element array of IMOD display elements displaying an image.

FIG. 5B is a timing diagram for common and segment signals that may be used to write data to the display elements illustrated in FIG. 5A.

FIGS. 6A and 6B are schematic exploded partial perspective views of a portion of an electromechanical systems (EMS) package including an array of EMS elements and a backplate.

FIG. 7 is an illustration of a transfer curve for I_{d} (drain current) vs. V_{gs} (gate-to-source voltage) for an exemplary NMOS transistor.

FIG. 8 is a system block diagram illustrating components within a row driver circuit.

FIG. 9A is a circuit schematic of a row driver circuit module.

FIG. 9B is an illustration of driven nodes of the row driver circuit module of FIG. 9A.

FIG. 9C is an illustration of leakage currents for the row driver circuit module of FIG. 9A.

FIG. 10 is a timing diagram for the row driver circuit module of FIG. 9A.

FIG. 11 is an illustration of a preferred node without leakage and a node with leakage.

FIG. 12 is a circuit schematic of a row driver circuit module with reduced leakage and static power consumption.

FIG. 13 is a circuit schematic of a common driver circuit module.

FIG. 14 is a timing diagram for the common driver circuit module of FIG. 13.

FIG. 15 is a circuit schematic of a common driver circuit module with reduced leakage.

FIG. 16 is a block diagram illustrating a method for reducing leakage at a floating node.

FIGS. 17A and 17B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Active matrix flat panel displays such as active matrix liquid crystal displays, organic light emission displays, and interferometric modulator (IMOD) displays have thin film transistors (TFTs) on glass substrates. The TFTs may be used to create row and common driver circuits for addressing display elements as described above.

Amorphous oxide semiconductor TFTs, such as indium gallium zinc oxide (IGZO) TFTs, may be used to replace amorphous silicon and low temperature and polysilicon TFTs. However, IGZO TFTs have a high sub-threshold leakage current (e.g., an unwanted drain current when the transistor gate voltage is zero). Preferably, sub-threshold leakage current should be reduced to ensure a circuit operates properly and reduces static power consumption.

Some implementations of the subject matter described in this disclosure reduce leakage current in row and common driver circuits. In particular, leakage at a variety of internal floating nodes may be reduced by providing feedback from the internal floating nodes to “feedback” transistors configured to bias other nodes such that leakage through turned-off transistors is reduced. Additionally, leakage contributing to static power consumption may also be reduced by employing low voltage power supplies such as a low voltage (“VSS”) and a lower than VSS voltage (“VSSL”).

Particular implementations of the subject matter described in this disclosure can be implemented to realize one or more of the following potential advantages. Reducing unwanted leakage current causing a discharge of a floating node may prevent a deviation from the intended operation of a circuit. For example, leakage currents may cause a floating node to discharge to a low or intermediate voltage level from an expected high voltage level. Moreover, floating nodes may cause an output of a circuit to become undriven or floating. The output may unexpectedly pick up noise through capacitive coupling. If the output is used to address display elements, the pixel color and/or grey level of the display elements may be degraded. Additionally, reducing static power consumption may lower power usage and, for example, increase battery life of devices including display devices such as tablets, laptops, phones, and e-book readers.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

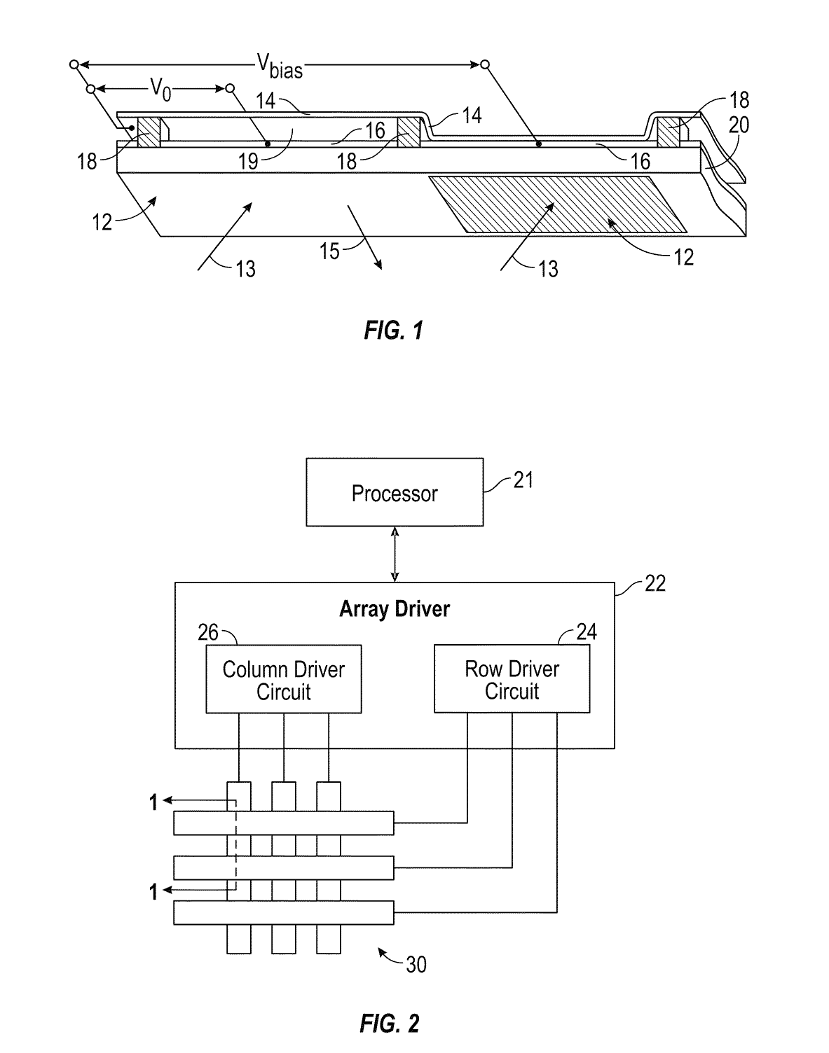

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

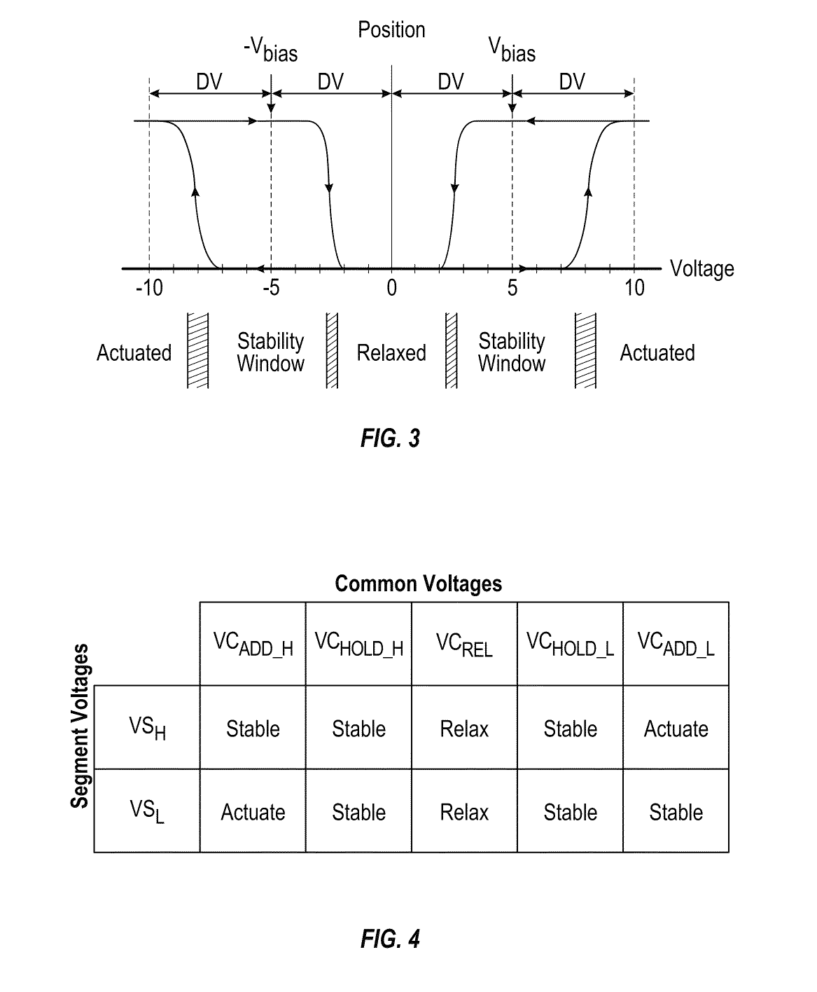

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

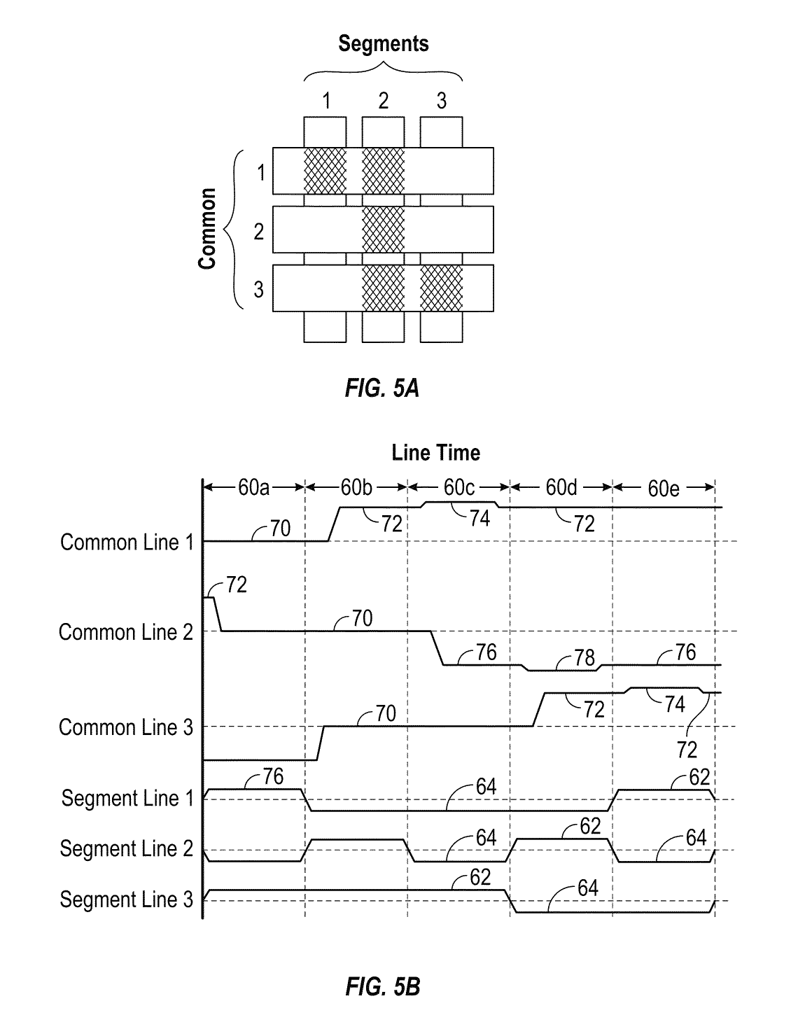

FIG. 3 is a graph illustrating movable reflective layer position versus applied voltage for an IMOD display element. For IMODs, the row/column (i.e., common/segment) write procedure may take advantage of a hysteresis property of the display elements as illustrated in FIG. 3. An IMOD display element may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3-7 volts, in the example of FIG. 3, exists where there is a window of applied voltage within which the element is stable in either the relaxed or actuated state. This is referred to herein as the “hysteresis window” or “stability window.” For a display array 30 having the hysteresis characteristics of FIG. 3, the row/column write procedure can be designed to address one or more rows at a time. Thus, in this example, during the addressing of a given row, display elements that are to be actuated in the addressed row can be exposed to a voltage difference of about 10 volts, and display elements that are to be relaxed can be exposed to a voltage difference of near zero volts. After addressing, the display elements can be exposed to a steady state or bias voltage difference of approximately 5 volts in this example, such that they remain in the previously strobed, or written, state. In this example, after being addressed, each display element sees a potential difference within the “stability window” of about 3-7 volts. This hysteresis property feature enables the IMOD display element design to remain stable in either an actuated or relaxed pre-existing state under the same applied voltage conditions. Since each IMOD display element, whether in the actuated or relaxed state, can serve as a capacitor formed by the fixed and moving reflective layers, this stable state can be held at a steady voltage within the hysteresis window without substantially consuming or losing power. Moreover, essentially little or no current flows into the display element if the applied voltage potential remains substantially fixed.

In some implementations, a frame of an image may be created by applying data signals in the form of “segment” voltages along the set of column electrodes, in accordance with the desired change (if any) to the state of the display elements in a given row. Each row of the array can be addressed in turn, such that the frame is written one row at a time. To write the desired data to the display elements in a first row, segment voltages corresponding to the desired state of the display elements in the first row can be applied on the column electrodes, and a first row pulse in the form of a specific “common” voltage or signal can be applied to the first row electrode. The set of segment voltages can then be changed to correspond to the desired change (if any) to the state of the display elements in the second row, and a second common voltage can be applied to the second row electrode. In some implementations, the display elements in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

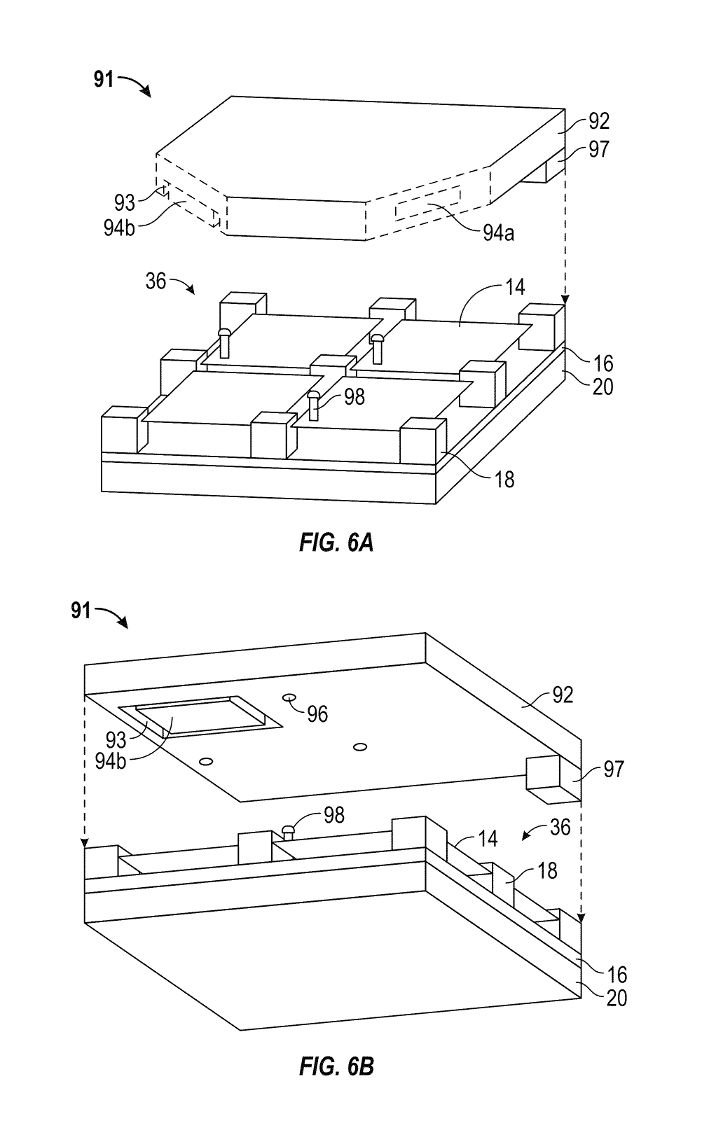

The combination of segment and common signals applied across each display element (that is, the potential difference across each display element or pixel) determines the resulting state of each display element. FIG. 4 is a table illustrating various states of an IMOD display element when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

As illustrated in FIG. 4, when a release voltage VC_{REL} is applied along a common line, all IMOD display elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator display elements or pixels (alternatively referred to as a display element or pixel voltage) can be within the relaxation window (see FIG. [#C], also referred to as a release window) both when the high segment voltage VS_{H} and the low segment voltage VS_{L} are applied along the corresponding segment line for that display element.

When a hold voltage is applied on a common line, such as a high hold voltage VC_{HOLD}_{_{—}}_{H} or a low hold voltage VC_{HOLD}_{_{—}}_{L}, the state of the IMOD display element along that common line will remain constant. For example, a relaxed IMOD display element will remain in a relaxed position, and an actuated IMOD display element will remain in an actuated position. The hold voltages can be selected such that the display element voltage will remain within a stability window both when the high segment voltage VS_{H} and the low segment voltage VS_{L} are applied along the corresponding segment line. Thus, the segment voltage swing in this example is the difference between the high VS_{H} and low segment voltage VS_{L}, and is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that common line by application of segment voltages along the respective segment lines. The segment voltages may be selected such that actuation is dependent upon the segment voltage applied. When an addressing voltage is applied along a common line, application of one segment voltage will result in a display element voltage within a stability window, causing the display element to remain unactuated. In contrast, application of the other segment voltage will result in a display element voltage beyond the stability window, resulting in actuation of the display element. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having substantially no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation that could occur after repeated write operations of a single polarity.

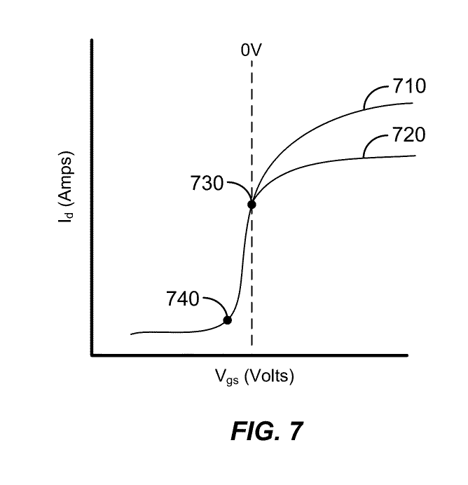

FIG. 5A is an illustration of a frame of display data in a three element by three element array of IMOD display elements displaying an image. FIG. 5B is a timing diagram for common and segment signals that may be used to write data to the display elements illustrated in FIG. 5A. The actuated IMOD display elements in FIG. 5A, shown by darkened checkered patterns, are in a dark-state, i.e., where a substantial portion of the reflected light is outside of the visible spectrum so as to result in a dark appearance to, for example, a viewer. Each of the unactuated IMOD display elements reflect a color corresponding to their interferometric cavity gap heights. Prior to writing the frame illustrated in FIG. 5A, the display elements can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. In some implementations, the segment voltages applied along segment lines 1, 2 and 3 will have no effect on the state of the IMOD display elements, as none of common lines 1, 2 or 3 are being exposed to voltage levels causing actuation during line time 60a (i.e., VC_{REL}—relax and VC_{HOLD} _{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the display element voltage across modulators (1,1) and (1,2) is greater than the high end of the positive stability window (i.e., the voltage differential exceeded a characteristic threshold) of the modulators, and the modulators (1,1) and (1,2) are actuated. Conversely, because a high segment voltage 62 is applied along segment line 3, the display element voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the display element voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state. Then, the voltage on common line 2 transitions back to the low hold voltage 76.

Finally, during the fifth line time 60e, the voltage on common line 1 remains at high hold voltage 72, and the voltage on common line 2 remains at the low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 display element array is in the state shown in FIG. [#EA], and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the display element voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5A. In some other implementations, voltages applied along common lines or segment lines may vary to account for variations in the actuation and release voltages of different modulators, such as modulators of different colors.

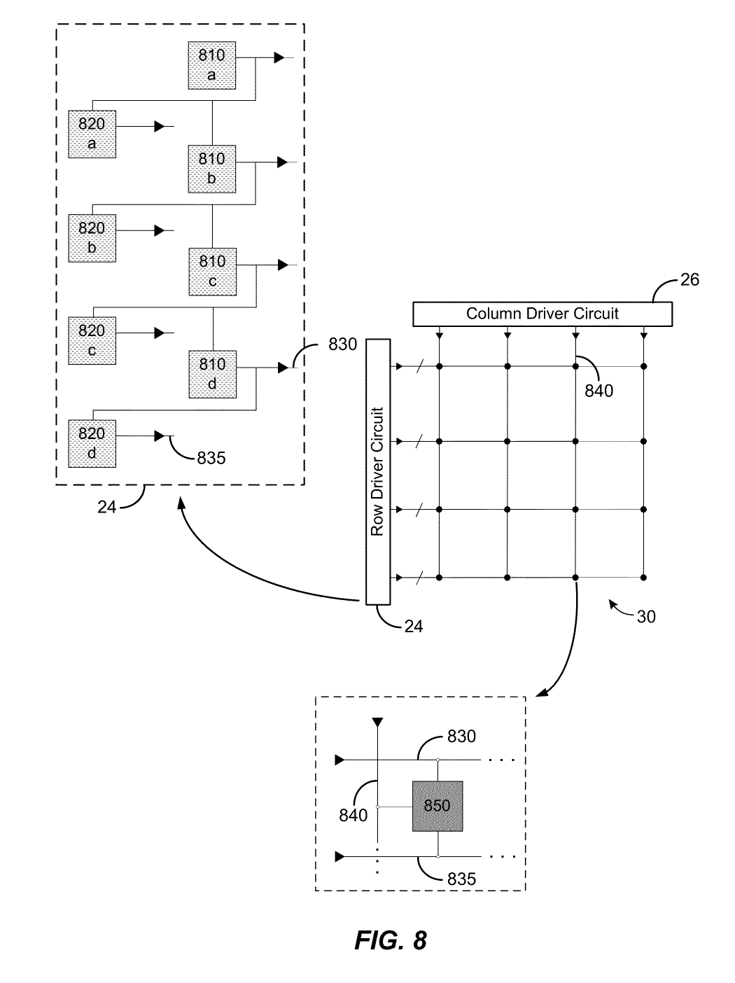

FIGS. 6A and 6B are schematic exploded partial perspective views of a portion of an EMS package 91 including an array 36 of EMS elements and a backplate 92. FIG. 6A is shown with two corners of the backplate 92 cut away to better illustrate certain portions of the backplate 92, while FIG. 6B is shown without the corners cut away. The EMS array 36 can include a substrate 20, support posts 18, and a movable layer 14. In some implementations, the EMS array 36 can include an array of IMOD display elements with one or more optical stack portions 16 on a transparent substrate, and the movable layer 14 can be implemented as a movable reflective layer.

The backplate 92 can be essentially planar or can have at least one contoured surface (e.g., the backplate 92 can be formed with recesses and/or protrusions). The backplate 92 may be made of any suitable material, whether transparent or opaque, conductive or insulating. Suitable materials for the backplate 92 include, but are not limited to, glass, plastic, ceramics, polymers, laminates, metals, metal foils, Kovar and plated Kovar.

As shown in FIGS. 6A and 6B, the backplate 92 can include one or more backplate components 94a and 94b, which can be partially or wholly embedded in the backplate 92. As can be seen in FIG. 6A, backplate component 94a is embedded in the backplate 92. As can be seen in FIGS. 6A and 6B, backplate component 94b is disposed within a recess 93 formed in a surface of the backplate 92. In some implementations, the backplate components 94a and/or 94b can protrude from a surface of the backplate 92. Although backplate component 94b is disposed on the side of the backplate 92 facing the substrate 20, in other implementations, the backplate components can be disposed on the opposite side of the backplate 92.

The backplate components 94a and/or 94b can include one or more active or passive electrical components, such as transistors, capacitors, inductors, resistors, diodes, switches, and/or integrated circuits (ICs) such as a packaged, standard or discrete IC. Other examples of backplate components that can be used in various implementations include antennas, batteries, and sensors such as electrical, touch, optical, or chemical sensors, or thin-film deposited devices.

In some implementations, the backplate components 94a and/or 94b can be in electrical communication with portions of the EMS array 36. Conductive structures such as traces, bumps, posts, or vias may be formed on one or both of the backplate 92 or the substrate 20 and may contact one another or other conductive components to form electrical connections between the EMS array 36 and the backplate components 94a and/or 94b. For example, FIG. 6B includes one or more conductive vias 96 on the backplate 92 which can be aligned with electrical contacts 98 extending upward from the movable layers 14 within the EMS array 36. In some implementations, the backplate 92 also can include one or more insulating layers that electrically insulate the backplate components 94a and/or 94b from other components of the EMS array 36. In some implementations in which the backplate 92 is formed from vapor-permeable materials, an interior surface of backplate 92 can be coated with a vapor barrier (not shown).

The backplate components 94a and 94b can include one or more desiccants which act to absorb any moisture that may enter the EMS package 91. In some implementations, a desiccant (or other moisture absorbing materials, such as a getter) may be provided separately from any other backplate components, for example as a sheet that is mounted to the backplate 92 (or in a recess formed therein) with adhesive. Alternatively, the desiccant may be integrated into the backplate 92. In some other implementations, the desiccant may be applied directly or indirectly over other backplate components, for example by spray-coating, screen printing, or any other suitable method.

In some implementations, the EMS array 36 and/or the backplate 92 can include mechanical standoffs 97 to maintain a distance between the backplate components and the display elements and thereby prevent mechanical interference between those components. In the implementation illustrated in FIGS. 6A and 6B, the mechanical standoffs 97 are formed as posts protruding from the backplate 92 in alignment with the support posts 18 of the EMS array 36. Alternatively or in addition, mechanical standoffs, such as rails or posts, can be provided along the edges of the EMS package 91.

Although not illustrated in FIGS. 6A and 6B, a seal can be provided which partially or completely encircles the EMS array 36. Together with the backplate 92 and the substrate 20, the seal can form a protective cavity enclosing the EMS array 36. The seal may be a semi-hermetic seal, such as a conventional epoxy-based adhesive. In some other implementations, the seal may be a hermetic seal, such as a thin film metal weld or a glass frit. In some other implementations, the seal may include polyisobutylene (PIB), polyurethane, liquid spin-on glass, solder, polymers, plastics, or other materials. In some implementations, a reinforced sealant can be used to form mechanical standoffs.

In alternate implementations, a seal ring may include an extension of either one or both of the backplate 92 or the substrate 20. For example, the seal ring may include a mechanical extension (not shown) of the backplate 92. In some implementations, the seal ring may include a separate member, such as an O-ring or other annular member.

In some implementations, the EMS array 36 and the backplate 92 are separately formed before being attached or coupled together. For example, the edge of the substrate 20 can be attached and sealed to the edge of the backplate 92 as discussed above. Alternatively, the EMS array 36 and the backplate 92 can be formed and joined together as the EMS package 91. In some other implementations, the EMS package 91 can be fabricated in any other suitable manner, such as by forming components of the backplate 92 over the EMS array 36 by deposition.

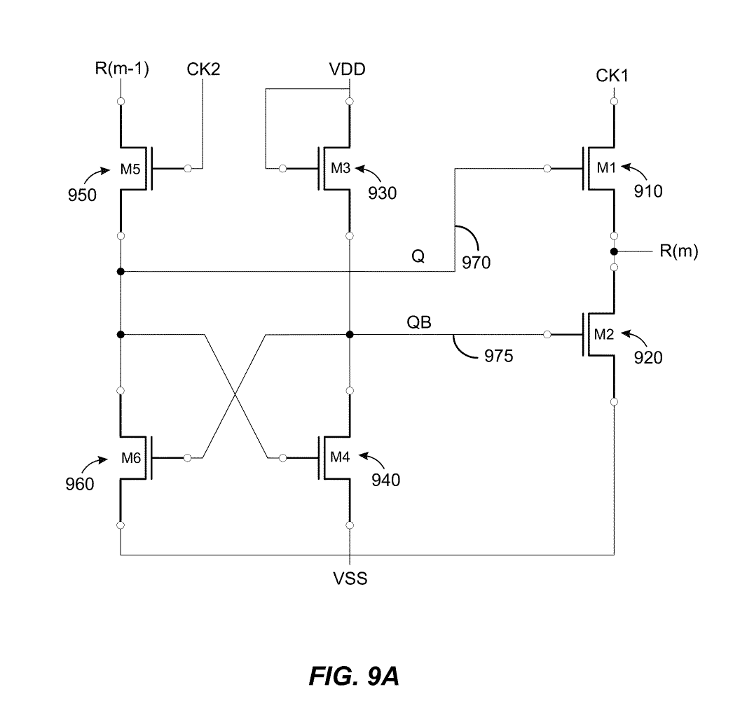

FIG. 7 is an illustration of a transfer curve for I_{d} (drain current) vs. V_{gs} (gate-to-source voltage) for an exemplary NMOS transistor. In FIG. 7, curves 710 and 720 may represent two different V_{ds} (drain-to-source voltage) biases. For example, curve 710 may be associated with a V_{ds} of 10.1 V (Volts) and curve 720 may be associated with a V_{ds} of 0.1 V.

As seen in FIG. 7, I_{d} is lower at lower V_{gs} values. Some transistors, such as depletion mode field effect transistors, show a negative turn-on voltage (Vₒₙ) which is the V_{gs} where I_{d} starts to increase abruptly with increasing V_{gs}. For example, in FIG. 7, point 740 may be associated with a Vₒₙ of −1 V. Moreover, at point 730, or a 0 V V_{gs} bias, I_{d} may approximately be 1 nA (nanoampere) or higher.

Ideally, when V_{gs}<Vₜₕ (threshold voltage), such as at point 730 when V_{gs} is 0 V, an NMOS transistor should be turned off, and thus I_{d} should be 0 A. However, a sub-threshold leakage occurs, as indicated by the non-zero y-axis I_{d} of points 730 and 740 on the transfer curves of FIG. 7. The sub-threshold leakage may increase power consumption and/or interfere with the intended operation of a circuit.

Accordingly, biasing the V_{gs} of an NMOS transistor lower may reduce the sub-threshold leakage. That is, biasing V_{gs} at point 740, or any lower V_{gs} value, rather than point 730 at 0 V V_{gs}, reduces the I_{d} sub-threshold leakage.

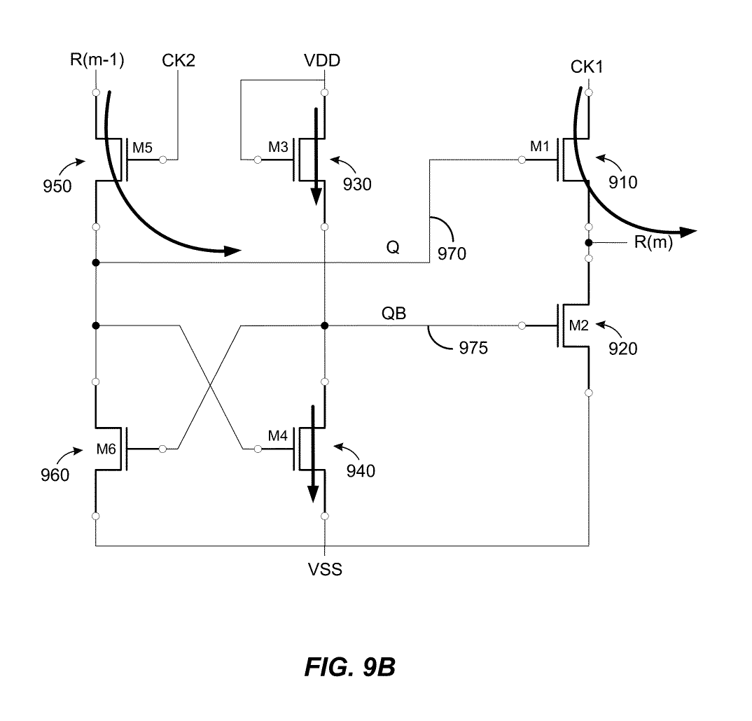

FIG. 8 is a system block diagram illustrating components within a row driver circuit. Moreover, FIG. 8 depicts an implementation of the row driver circuit 24 and the column driver circuit 26 of array driver 22 that provide signals to, for example the display array or panel 30, as previously discussed. In FIG. 8, row driver circuit 24 may include multiple row driver circuit modules 810a, 810b, 810c, and 810d. Row driver circuit 24 may also include multiple common driver circuit modules 820a, 820b, 820c, and 820d. In some implementations, even and odd row and common signals may be provided by left and right row driver and common driver circuits, or vice versa.

In the circuit of FIG. 8, each row driver circuit module drives a row signal of display array 30. For example, row driver circuit module 810a may drive a first row of display array 30. Row driver circuit module 810b may drive a second row of display array 30. Row driver circuit module 810c may drive a third row of display array 30. Finally, row driver circuit module 810d may drive a fourth row of display array 30.

Additionally, each common driver circuit module provides a bias to a given row of pixels that may be synchronously updated with a row refresh. For example, common driver circuit 820a may drive a common signal for a first row of display array 30. Common driver circuits 820b, 820c, and 820d similarly provide a common signal for rows of display elements.

In an implementation, the output of each row driver circuit module may also be provided to the next row driver circuit module as well as a common driver circuit module. That is, the output that is driving the particular row of display array 30 may also be provided as an input to the next row driver circuit module and a common driver circuit module. For example, the output of row driver circuit module 810a is used to drive a row of display array 30 as well as provided as an input to row driver circuit module 810b and common driver circuit module 820a.

Accordingly, in an implementation, row driver circuit 24 may include multiple modules used to drive particular rows of display array 30. Moreover, the modules may be interconnected (i.e., the output that is used to drive the rows may also be provided to another module). Additionally, the output may be provided to modules used to drive a common signal for rows of display array 30.

As an example, display element 850 in the fourth row may be provided row signal 830 from row driver circuit module 810d, common signal 835 from common driver circuit module 820d, and column signal 840 from column driver circuit 26. The implementation of display element 850 may include a variety of different designs. In some implementations, display element 850 may include a transistor with its gate coupled to 830 row signal and column signal 840 provided to the drain. Common signal 835 may provide a bias to other components within display element 850. In some implementations, display element 850 may have multiple common signals.

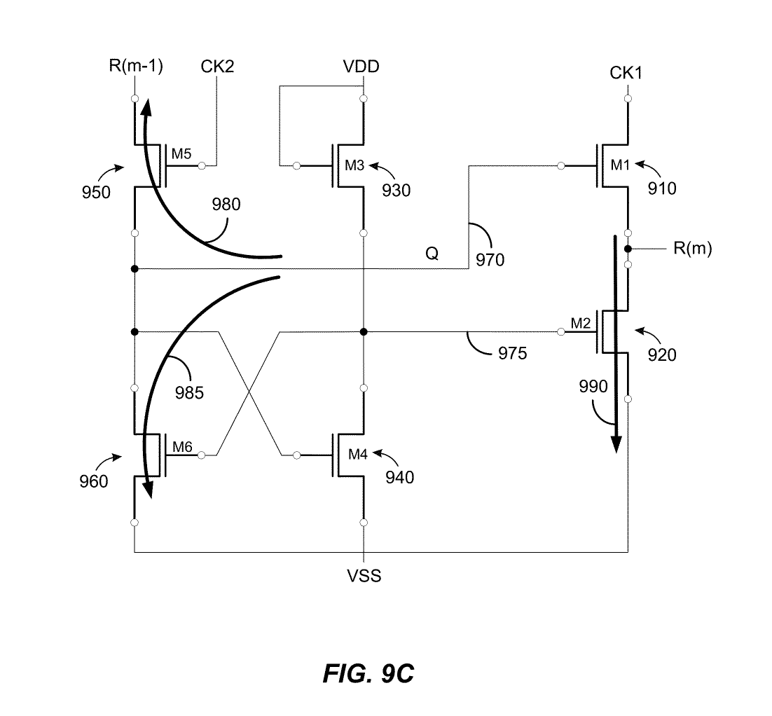

FIG. 9A is a circuit schematic of a row driver circuit module. In an implementation, the row driver circuit module of FIG. 9A may be a row driver circuit module 810a-810d of FIG. 8. The circuit of FIG. 9A includes six switches implemented as six NMOS transistors M1 910, M2 920, M3 930, M4 940, M5 950, and M6 960. In some implementations, the circuit may be implemented with PMOS transistors. Additionally, in some implementations, other types of transistors or components may be used.

In FIG. 9A, the row driver circuit module includes a variety of inputs and outputs: clocks CK1 and CK2, input R(m−1), which is the output from a prior row driver circuit module (e.g., the output of row driver circuit module 810a being provided as an input to row driver circuit module 810b), output R(m), high supply voltage VDD, and low supply voltage VSS. The first start signal to row driver circuit module 810a is externally provided.

Transistors M1 910 and M2 920 are coupled together to define an output node providing output R(m). Transistor M1 910 is further coupled to clock CK1 and its gate, or control, terminal is coupled with transistor M5 950, defining a charge node Q 970. Transistor M2 920 is also coupled to the low power supply voltage VSS. Transistor M5 950 is further coupled to input R(m−1), which is the output from a prior row driver circuit module, as described above. Moreover, the gate terminal of transistor M5 950 is coupled to a second clock CK2. Transistor M3 930 has a terminal coupled with VDD along with the gate terminal. Transistor M3 930 is also coupled with transistor M4 940, as well as the gates of transistors M6 960 and M2 920, defining a QB (i.e., Q bar, or the inverse of Q) node 975. Transistor M4 940 is also coupled to the low power supply voltage VSS. The control or gate terminal of transistor M4 940 is also coupled to the charge node Q 970. Finally, transistor M6 960 is also coupled between VSS and the charge node Q 970.

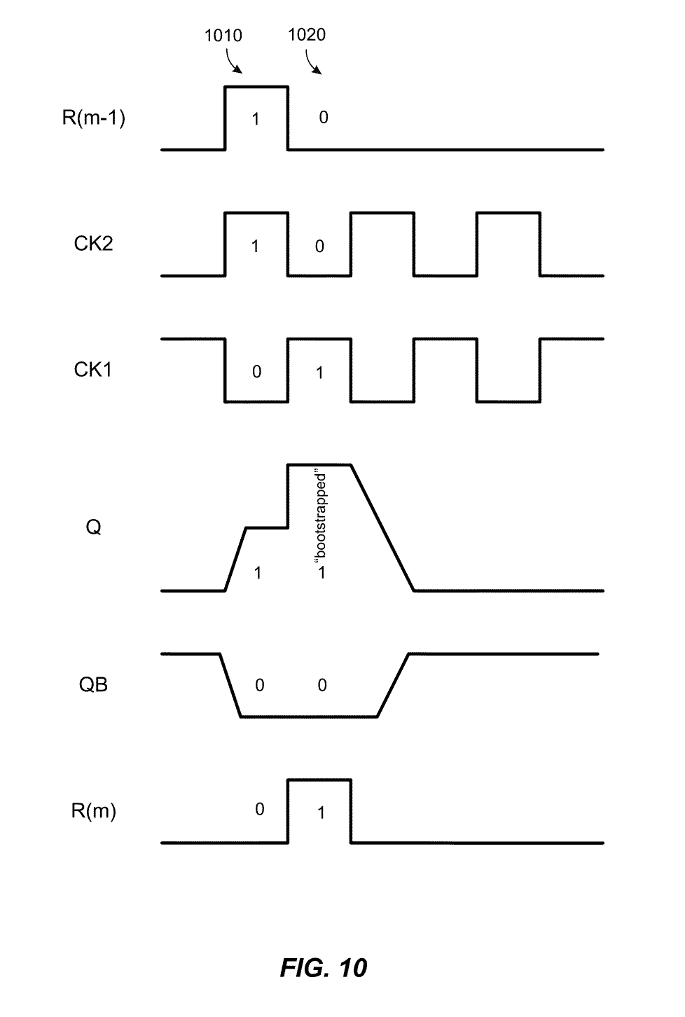

FIG. 10 is a timing diagram for the row driver circuit module of FIG. 9A. The timing diagram includes the signals for input R(m−1), clocks CK1 and CK2, output R(m), internal signals Q (i.e., charge node Q 970) and QB (i.e., QB node 975), and output R(m). In some implementations, clocks CK1 and CK2 may be out of phase with each other. For example, clocks CK1 and CK2 may be 180 degrees out of phase with each other. That is, when clock CK1 is high, clock CK2 is low, and vice versa.

At time 1010, input R(m−1) is high (indicated as “1” in FIG. 10), CK2 is high, and CK1 is low (indicated as “0” in FIG. 10). As such, transistor M5 950 turns on because CK2 is high and coupled to the gate terminal of transistor M5 950. Therefore, the charge node Q 970 is charged high because R(m−1) is high. Because charge node Q 970 is high, transistor M1 910 turns on. At time 1010, CK1 is low, and therefore, output R(m) is low. QB is charged low because if the charge node Q node is high, transistor M4 940 turns on and pulls QB low to VSS. In some implementations, transistor M3 930 may always be on, for example, because its gate terminal is coupled to high power supply VDD. However, transistor M4 940 may be sized larger than transistor M3 930, and therefore transistor M4 940 may be able to overcome any contention issues from transistor M3 930 trying to pull QB node 975 high to VDD while transistor M4 940 is pulling the same node low to VSS. Because the QB node 975 is low and coupled to the gate terminal of transistor M6 960, the transistor is turned off (i.e., the charge node Q 970 is not pulled low to VSS). Transistor M2 920 is also turned off because its gate, or control, terminal is also coupled to QB node 975.

FIG. 9B is an illustration of driven nodes of the row driver circuit module of FIG. 9A. FIG. 9B shows the nodes driven (i.e., pulled high or low) at time 1010 by the turned on transistors (i.e., transistors M5 950, M3 930, M1 910, and M4 940).

At time 1020 on FIG. 10, R(m−1) is low, CK2 is low, and CK1 is high. As such, transistor M5 950 turns off because CK2 is low and coupled to the gate terminal of transistor M5 950. Therefore, transistor M5 950 is no longer driving charge node Q 970. However, transistor M6 960 is also off and therefore not pulling charge node Q 970 low to VSS, as previously discussed. Accordingly, charge node Q 970 is no longer being driven and is, therefore, floating (i.e., it is not being pulled high or low). Transistor M1 910 remains turned on because the undriven charge node Q 970 is charged high. Thus, output R(m) follows clock CK1 high.

However, capacitive coupling between clock CK1 through the gate of transistor M1 910 and charge node Q 970 may cause the charge node Q 970 to “bootstrap,” or experience a boosting voltage, because undriven, or floating, nodes are more susceptible to capacitive coupling. Accordingly, the voltage at charge node Q 970 is stepped up beyond the level set by the previous clock cycle, as indicated by the “bootstrapped” label in FIG. 10.

Preferably, when charge node Q 970 is charged high and left floating, the node should not be discharged, i.e., the voltage level should remain constant. However, as previously discussed with respect to FIG. 7, leakage may occur in transistors. In the circuit of FIG. 9A, leakage at transistors M5 and M6 may discharge charge node Q 970. For example, for transistor M5 at time 1020, V_{gs} may be 0 V (because the biases of clock signal CK2 at the gate terminal and R(m−1) at the source terminal are both 0 V) and V_{ds} may be 20 V (because the biases of R(m−1) at the source is 0 V and charge node Q 970 at the drain may be bootstrapped, for example, to 20 V). As such, in view of the transfer curve of FIG. 7, an unwanted I_{d} through transistors M5 950 and M6 960 discharges charge node Q 970. That is, because V_{gs} is 0 V, for example, at point 730 of FIG. 7, an I_{d} indicated by the y-axis may be observed as discharging charge node Q 970. Leakage through transistor M6 960 occurs similar to transistor M5 950 because, like the gate terminal input CK2 of transistor M5 950, the gate terminal of transistor M6 960 is coupled with QB node 975, which is low when charge node Q is high and the source terminal of transistor M6 960 is the low power supply voltage VSS.

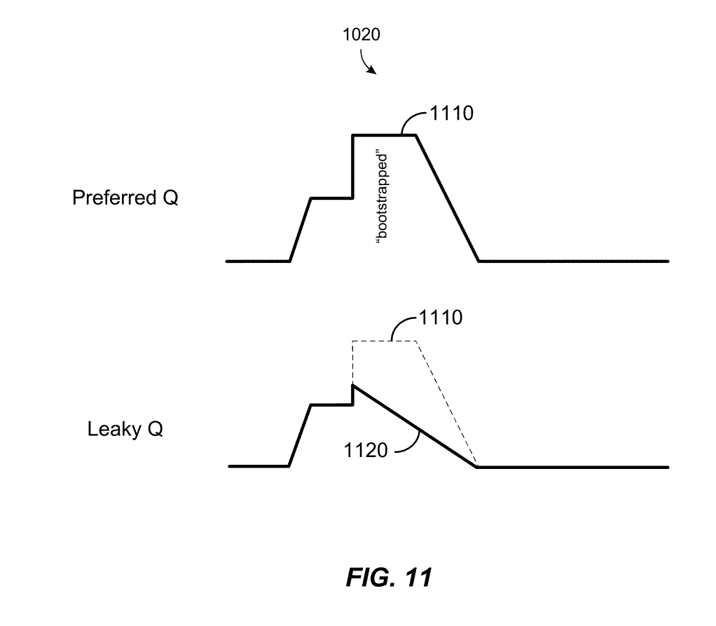

FIG. 11 is an illustration of a preferred node without leakage and a node with leakage. For example, in FIG. 11, a simplified signal for charge node Q is shown for both preferred Q 1110 and leaky Q 1120. Preferred Q node 1110 experiences no discharge when floating at time 1020. However, leaky Q 1120 begins to discharge during the bootstrap period when charge node Q 970 is floating. Accordingly, the voltage level of leaky Q 1120 is lower than preferred Q 1110 during time 1020. As such, the circuit may not function properly. For example, leaky Q 1120 may enter an intermediate voltage range or go low when it is expected to be high.

Additionally, transistor M2 920 of the row driver circuit module of FIG. 9A contributes to static power consumption. If charge node Q 970 is high, transistor M1 910 is turned on. Therefore, transistor M2 920 is turned off, as previously discussed. However, leakage may occur at transistor M2 920. Accordingly, maintaining the R(m) output at a high voltage level causes extra power consumption. That is, when R(m) is driven high by CK1 and transistor M1 910, leakage through transistor M2 920 contributes to static power consumption.

FIG. 9C is an illustration of leakage currents for the row driver circuit module of FIG. 9A. In FIG. 9C, leakages 980 and 985 are associated with sub-threshold leakages through turned-off transistors M5 950 and M6 960. Leakage 990 is the sub-threshold leakage through transistor M2 920 that contributes to static power consumption when the R(m) output node is driven high.

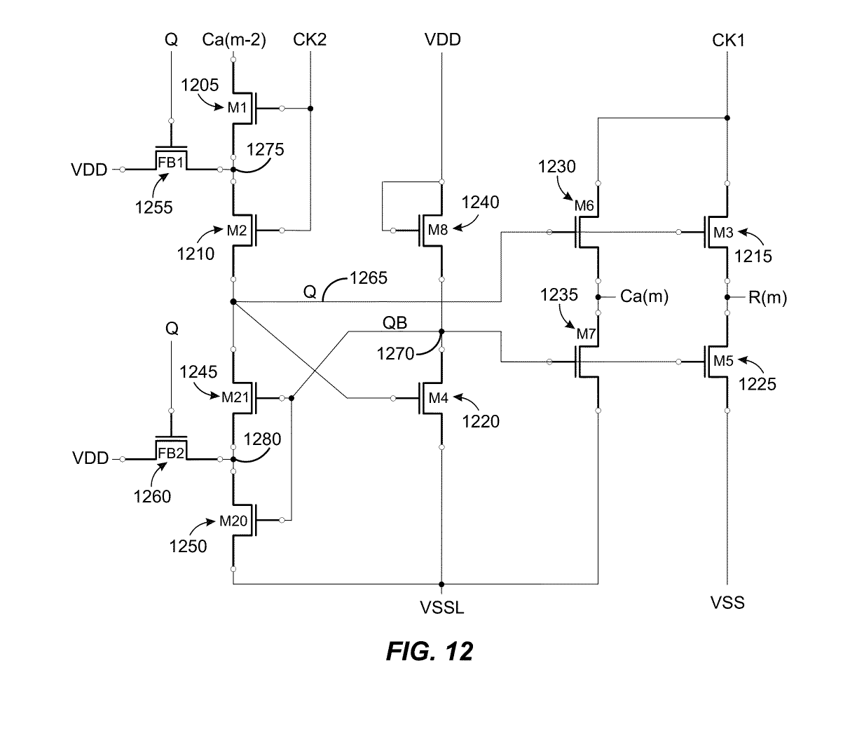

FIG. 12 is a circuit schematic of a row driver circuit module with reduced leakage and static power consumption. In an implementation, the row driver circuit module of FIG. 12 may be a row driver circuit module 810a-810d of FIG. 8. The circuit of FIG. 12 includes twelve NMOS transistors: M1 1205, M2 1210, M3 1215, M4 1220, M5 1225, M6 1230, M7 1235, M8 1240, M20 1250, M21 1245, FB1 1255, and FB2 1260. In some implementations, the circuit may be implemented with PMOS transistors. Additionally, in some implementations, other types of transistors or components may be used.

The row driver circuit module of FIG. 12 includes similar inputs as the row driver circuit module of FIG. 9A and similarly represents one of multiple stages of a row driver circuit array for driving a corresponding array of display elements. However, the row driver circuit module of FIG. 12 includes a third power supply, VSSL. In some implementations, VSSL may be a power supply at a lower voltage than VSS. The circuit also includes a second output Ca(m). The low voltage output of R(m) is VSS because transistor M5 1225 is coupled to VSS. However, the low voltage of output Ca(m) is VSSL because transistor M7 1235 is coupled to VSSL. In some implementations, Ca(m) is also provided as an input to another stage (i.e., another row driver circuit module) rather than R(m). For instance, in FIG. 12, the Ca(m−2) input of transistor M1 1205 may be from another row driver circuit module. The Ca(m−2) input may be provided from any prior or latter row driver circuit module. In some implementations, the Ca(m−2) output may be from a row driver circuit module driving a row of display array 30 adjacent (e.g., immediately before or after) to the row being driven by the circuit of FIG. 12. In another implementation, the Ca(m−2) output may be from a row driver circuit module driving a row of display array 30 two rows from the row being driven by the circuit of FIG. 12 (e.g., the output of a row driver circuit module associated with row one may be provided to a row driver circuit module associated with row three).

The circuit of FIG. 12 includes some similar functionality to the circuit of FIG. 9A. For example, charge node Q 1265 is also driven high and then floated during the bootstrap mode, similar to charge node Q 970 of FIG. 9A. However, the leakage current at transistor M2 1210 and M21 1245 may be reduced to reduce the discharge of charge node Q 1265. Accordingly, the leakage current of FIG. 12 is lower than the leakage current of the circuit of FIG. 9A. Moreover, the static power consumption at the R(m) output may also be reduced.

In an implementation, transistors M1 1205 and M2 1210 may be coupled together to define a feedback node 1275. Likewise, transistors M21 1245 and M20 1250 may be coupled together to define a second feedback node 1280. The feedback nodes 1275 and 1280 are also coupled with feedback transistor FB1 1255 and feedback transistor FB2 1260, respectively. The gate terminals of feedback transistors FB1 1255 and FB2 1260 are coupled to charge node Q 1265. The drain terminals of feedback transistors FB1 1255 and FB2 1260 are coupled to high power supply VDD.

Feedback transistors FB1 1255 and FB2 1260 may be utilized to lower the V_{gs} of transistors M2 1210 and M21 1245, respectively, and therefore, reduce the leakage current contributing to the discharge of charge node Q 1265. As previously discussed, a lower V_{gs} provides a lower I_{d}, as seen in the transfer curve of FIG. 7. Accordingly, charging or biasing feedback nodes 1275 and 1280 such that transistors M2 1210 and M21 1245 have a lower V_{gs} may reduce the leakage current I_{d} when the transistors are turned off during time 1020 (i.e., during the bootstrap phase when charge node Q 1265 is floating).

For example, as previously discussed, feedback transistor FB1 1255's gate is coupled to charge node Q 1265, drain is coupled to VDD, and source is coupled to feedback node 1275. As previously discussed, charge node Q 1265 is charged high, floats, and enters a bootstrap mode to boost its voltage level. Accordingly, charge node Q 1265 is high, and because the node is also provided as feedback to the gate of transistor FB1 1255, feedback transistor FB1 1255 turns on. Feedback node 1275 charges high because the drain of feedback transistor FB1 1255 is coupled to high power supply VDD. The gate to transistor M2 1210 is CK2, which is low during the bootstrap phase at time 1020. Therefore, transistor M2 1210 is turned off. As such, transistor M2 1210's V_{gs} is negative. For example, if VDD is 5 V and CK2 is 0 V, then V_{gs} is −5 V. As previously discussed, a lower V_{gs} provides a lower I_{d}. Accordingly, the leakage current at transistor M2 1210 is reduced by lowering the V_{gs}. Thus, the discharge of charge node Q 1265 is reduced. Leakage is also reduced at transistor M21 1245 through a similar technique.

Additionally, static power consumption may be reduced by reducing the leakage at transistor M5 1225. Because a third power supply, VSSL, is provided, the static power consumption at the R(m) output of the row driver circuit module of FIG. 12 may also be reduced by lowering the V_{gs} of transistor M5 1225. In particular, VSSL is provided to the gate of transistor M5 1225 because QB node 1270 is pulled to VSSL by transistor M4 1220 during time 1020 (i.e., during the bootstrap phase). For example, if VSSL is −10 V and VSS is −5 V, then V_{gs} of transistor M5 1225 is −5 V. Accordingly, transistor M5 1225 may have a reduced leakage current when turned off, and therefore, static power consumption when driving output R(m) high (i.e., transistor M5 1225 is off and transistor M3 1215 is on) may be lower.

Additionally, as previously discussed, output Ca(m) may have a low voltage associated with VSSL while output R(m) may have a low voltage associated with VSS. In particular, charge node Q 1265 is coupled with the gates of transistors M6 1230 and M3 1215. Furthermore, node QB 1270 is coupled with the gates of transistors M7 1235 and M5 1225. Accordingly, when charge node Q 1265 is low and node QB 1270 is high, transistors M6 1230 and M3 1215 turn off and transistors M7 1235 and M5 1225 turn on. Thus, output Ca(m) is pulled low to VSSL and output R(m) is pulled low to VSS. When transistors M7 1235 and M5 1225 are turned off (i.e., node QB 1270 is low) and transistors M6 1230 and M3 1215 are turned on (i.e., charge node Q 1265 is high), both Ca(m) and R(m) follow CK1.

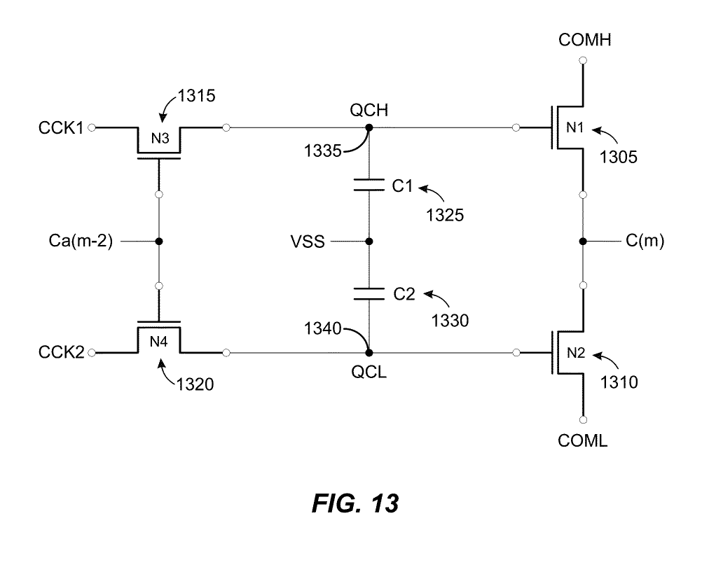

FIG. 13 is a circuit schematic of a common driver circuit module. In an implementation, the common driver circuit module of FIG. 13 may be a common driver circuit module 820a-820d of FIG. 8. In FIG. 13, the common driver circuit module includes four switches implemented with NMOS transistors (i.e., N1 1305, N2 1310, N4 1320, and N3 1315) and two capacitors (i.e., C1 1325 and C2 1330). In some implementations, the circuit may be implemented with PMOS transistors. Additionally, in some implementations, other types of transistors or components may be used.

In FIG. 13, the common driver circuit module includes a variety of inputs and outputs: clocks CCK1 and CCK2, low power supply VSS, COMH, COML, input Ca(m−2), which may be provided by a row driver circuit module, and output C(m). In an implementation, COMH and COML may provide high and low voltages, respectively, for output C(m).

Transistors N3 1315 and N1 1305 are coupled to define node QCH 1335. Capacitor C1 1325 is coupled between node QCH 1335 and VSS. Likewise, transistors N2 1310 and N4 1320 are coupled to define node QCL 1340. Capacitor C2 1330 is coupled between node QCL 1340 and VSS. Transistors N1 1305 and N2 1310 are also coupled to define an output node for output C(m). The gates of transistors N3 1315 and N4 1320 are driven by the Ca(m−2) input. The Ca(m−2) input may be an output of a row driver circuit module. Moreover, terminals of transistors N3 and N4 are provided clocks CCK1 and CCK2, respectively.

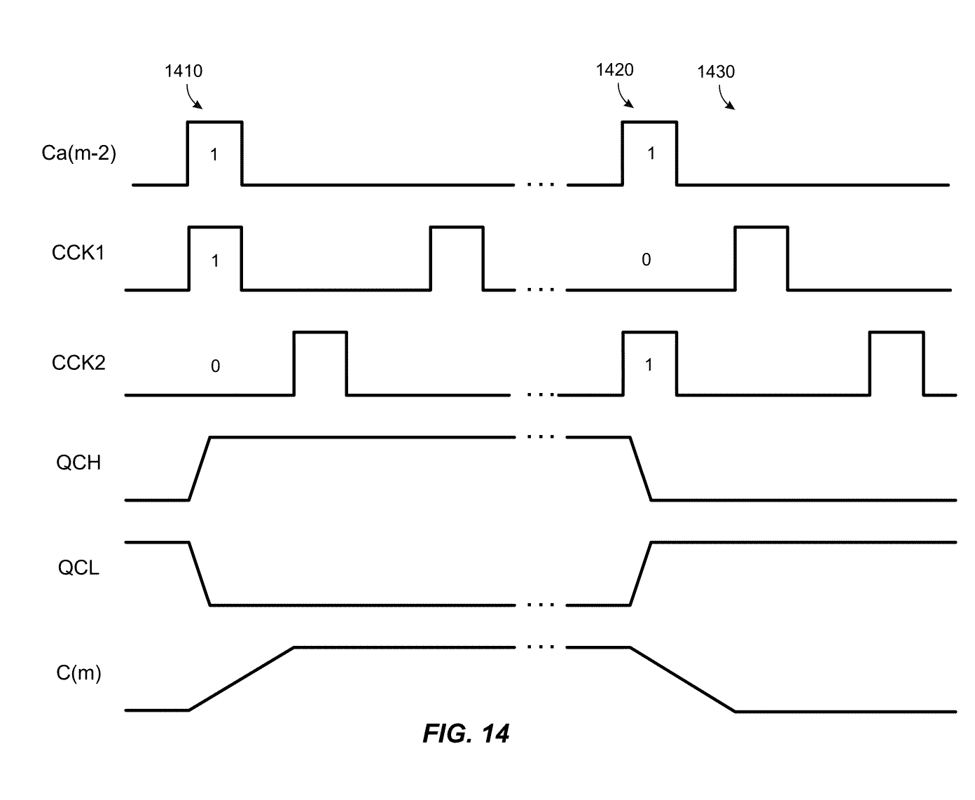

FIG. 14 is a timing diagram for the common driver circuit module of FIG. 13. The timing diagram includes the signals for input Ca(m−2), clocks CCK1 and CCK2, nodes QCH and QCL, and output C(m). In some implementations, clocks CCK1 and CCK2 may be out of phase with each other. Additionally, as seen in FIG. 14, clocks CCK1 and CCK2 may be configured to have a duty cycle lower than 50%. In some implementations, clocks CCK1 and CCK2 may be delayed compared to the Ca(m−2) input signal. In an implementation, the low voltage of Ca(m−2) may be VSSL, as discussed with respect to FIG. 12. Output C(m) may provide a high voltage at COMH and a low voltage at COML.

At time 1410, input Ca(m−2) is high (indicated as “1” in FIG. 14). Clock CCK1 is high and clock CCK2 is low. As such, both transistors N3 1315 and N4 1320 turn on because the gate terminal is high (i.e., the gate is coupled to Ca(m−2), which is high). Accordingly, node QCH 1335 begins to charge high because transistor N3 1315 is on and it is coupled to CCK1, which is high. Node QCL 1340 begins to discharge because transistor N4 1320 is on and it is coupled to CCK2, which is low. As node QCH 1335 goes high, transistor N1 1305 turns on and output C(m) follows COMH, which may be a high voltage. As node QCL 1340 goes low, transistor N2 1310 turns off.

At time 1420, Ca(m−2) is high, CCK1 is low, and CCK2 is high. Accordingly, QCH should be discharged (i.e., discharge capacitor C1 1555) and QCL should be charged high (i.e., charge capacitor C2 1550). Accordingly, C(m) follows COML, which may be a low voltage. As node QCH 1335 goes low, transistor N1 1305 turns off and transistor N2 1310 turns on as node QCL 1340 goes high.

However, in the circuit of FIG. 13, transistors N3 1315 and N4 1320 also experience leakage which can discharge floating nodes. In particular, nodes QCH 1335 and QCL 1340 may experience leakage through transistors N3 1315 and N4 1320, respectively, and therefore discharge capacitors C1 1325 and C2 1330. As previously discussed, either QCH or QCL should be high (i.e., if QCH is high, then QCL is low), and therefore, pull output C(m) to COMH or COML, respectively. However, if one of nodes QCH 1335 or QCL 1340 is supposed to be high, but is discharged, then C(m) may become undriven, or floating. A floating node may unexpectedly pick up noise through capacitive coupling. Since output C(m) is used to drive display elements, a floating C(m) may degrade pixel color and/or grey levels of the display elements.

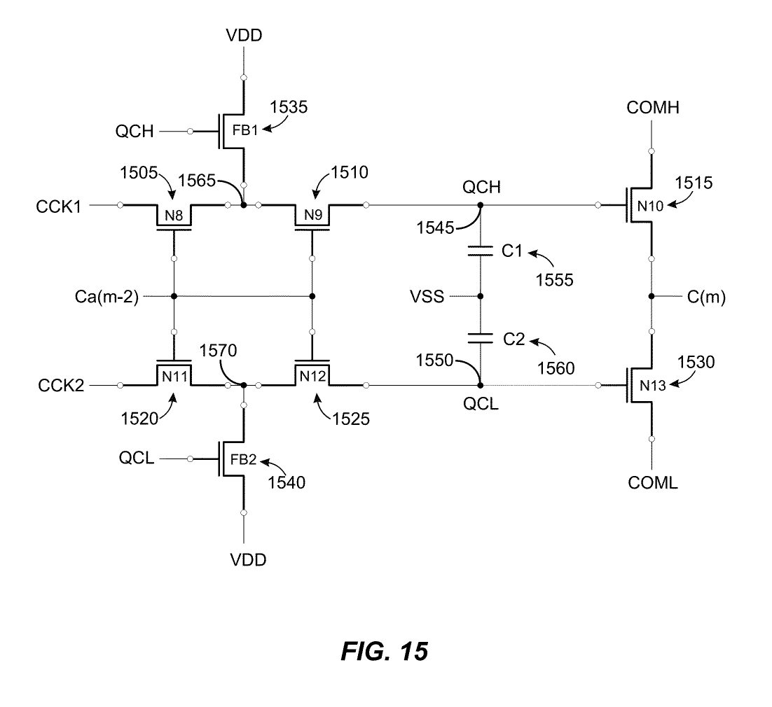

FIG. 15 is a circuit schematic of a common driver circuit module with reduced sub-threshold leakage. In an implementation, the common driver circuit module of FIG. 15 may be a common driver circuit module 820a-820d of FIG. 8. The circuit of FIG. 15 includes eight NMOS transistors: N8 1505, N9 1510, N10 1515, N11 1520, N12 1525, N13 1530, FB1 1535, and FB2 1540. The circuit also includes 2 capacitors: capacitors C1 1555 and C2 1560. In some implementations, the circuit may be implemented with PMOS transistors. Additionally, in some implementations, other types of transistors or components may be used.

The common driver circuit module of FIG. 15 includes similar inputs as the common driver circuit module of FIG. 13 and similarly represents one of multiple stages of a common driver circuit array for driving a corresponding array of display elements. However, the circuit of FIG. 15 includes an extra power supply, VDD, which may be a high voltage value at the same or different value than COMH. In some implementations, COMH may be at a higher voltage value than VDD, and vice versa.

The circuit of FIG. 15 includes some functionality similar to the circuit of FIG. 12. For example, either QCH node 1545 or QCL node 1550 may be high to drive transistor N10 1515 or N13 1530, respectively. However, leakage current causing the discharge of the node that is supposed to be floating yet charged high (i.e., QCH node 1545 or QCL node 1550) may be reduced. Accordingly, the leakage current of the circuit of FIG. 15 may be lower than the leakage current of the circuit of FIG. 13.

In an implementation, transistors N8 1505 and N9 1510 may be coupled together to define a feedback node 1565. The gates of transistors N8 1505 and N9 1510 may be coupled together to receive input Ca(m−2). Feedback transistor FB1 1535 may also be coupled to the feedback node and transistors N8 1505 and N9 1510. A terminal of feedback transistor FB1 1535 may be coupled to high power supply VDD, and the gate may be coupled to QCH node 1545. Likewise, transistors N11 1520 and N12 1525 may be coupled together to provide feedback node 1570. Feedback transistor FB2 1540 may be coupled to the feedback node 1570 and transistors N11 1520 and N12 1525. A terminal of feedback transistor FB1 1540 may be coupled to high power supply VDD, and the gate may be coupled to QCL node 1550.

Feedback transistors FB1 1535 and FB2 1540 may be utilized to lower the V_{gs} of transistors N9 1510 and N12 1525, respectively, and therefore, reduce the leakage current contributing to the discharge of the QCH node 1545 and QCL node 1550. As previously discussed, a lower V_{gs} provides a lower I_{d}, as seen in the transfer curve of FIG. 7. Accordingly, charging or biasing feedback nodes 1565 and 1570 such that transistors N9 1510 and N12 1525 have a lower V_{gs} may reduce the leakage current I_{d}, for example, at time 1430. That is, in the example of FIG. 14 at time 1430 (i.e., after time 1420 when input Ca(m−2) is low), leakage from QCL node 1550 through transistor N12 1525 may be reduced. Leakage from QCH node 1545 may also be reduced by biasing transistor N9 1510 to reduce its V_{gs}.

For example, as previously discussed, feedback transistor FB2 1540's gate is coupled to QCL node 1540, drain is coupled to VDD, and source is coupled to feedback node 1570. As previously discussed, if QCL node 1550 is high (and therefore QCH node 1545 is low), transistor N13 1530 turns on and output C(m) is pulled to COML. When input Ca(m−2) goes low at time 1430, QCL node 1550 is no longer being driven by transistor N12 1525, but is still charged high from time 1420. If QCL node 1550 is high, then feedback transistor FB2 1540 is turned on and charges feedback node 1570 to VDD because the drain of feedback transistor FB2 1540 is coupled to VDD. Accordingly, when transistor N12 1525 is turned off and QCL node 1550 is charged high, but floating or undriven, the V_{gs} of transistor N12 1525 may be adjusted to lower I_{d}. A similar technique may be applied for QCH node 1545.

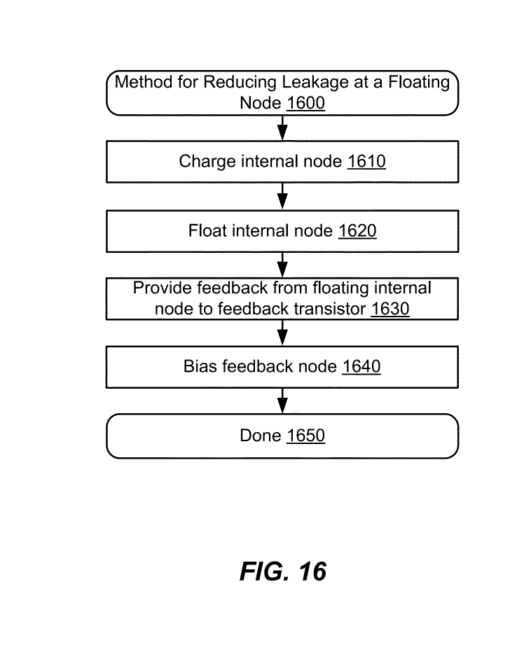

FIG. 16 is a block diagram illustrating a method for reducing leakage at a floating node. In method 1600, at block 1610, an internal node may be charged by a driving transistor. At block 1620, the internal node may no longer be driven (i.e., it is floating because the driving transistor is turned off and no other transistor is pulling the node high or low). At block 1630, feedback from the floating internal node may be provided to a feedback transistor. Accordingly, at block 1640, the feedback transistor may bias a feedback node such that the V_{gs} of the turned-off driving transistor is lower, and therefore, provide a reduced I_{d} leakage current from the internal floating node. The method ends at block 1650.

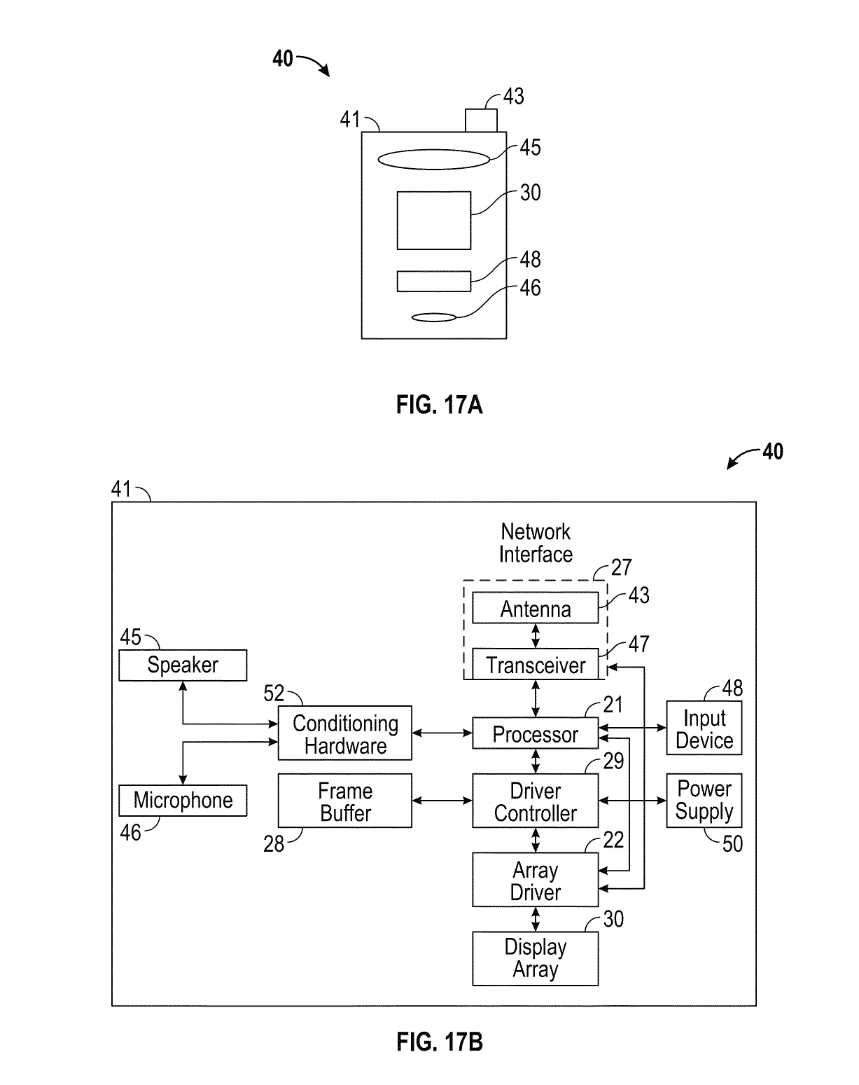

FIGS. 17A and 17B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 17A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 17A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

Though the circuits and techniques disclosed herein utilize NMOS transistors, any other type of element with the functionality of a switch may be used. For example, PMOS transistors, bipolar junction transistors, memristors, and other components may be used. Depletion-mode and enhancement-mode PMOS and NMOS transistors may also be used.

Though the circuits and techniques disclosed herein utilize 2-phase clock signals, any other type of clock system with any other type of duty ratio may be used.

Additionally, the circuits and techniques disclosed herein may be used in applications beyond drive circuitry of display elements. The circuits and techniques may be employed in any scenario where reducing leakage currents and/or static power consumption may be beneficial.

What is claimed is:

1. A driver circuit comprising:
a first input switch including:
a first switch having a first terminal and a second terminal, the first terminal coupled to receive an input signal, and
a second switch having a first terminal and a second terminal, the first terminal of the second switch coupled to the second terminal of the first switch to define a feedback node;
a first output switch including a third switch having a control terminal coupled to the second terminal of the second switch to define a charge node; and
a feedback switch having an output terminal and a control terminal, the output terminal coupled to the feedback node, the control terminal coupled to the charge node, the feedback switch configured to charge the feedback node responsive to a voltage level at the charge node.

2. The circuit of claim 1, wherein the charge node is charged to the voltage level by the second switch.

3. The circuit of claim 1, wherein the first switch of the first input switch further includes a control terminal, and the second switch of the first input switch further includes a control terminal, the control terminals of the first switch and the second switch coupled to each other.

4. The circuit of claim 1, wherein the charge node is floating when the second switch is turned off.

5. The circuit of claim 4, wherein the charge node is capable of providing a second voltage level to the feedback switch when the charge node is floating.

6. The circuit of claim 1, further comprising:
a fourth switch having a control terminal, a second terminal, and a third terminal, the control terminal of the fourth switch coupled to the charge node, and the second terminal of the fourth switch coupled to a first power supply; and
a fifth switch of the first output switch, the fifth switch having a control terminal, a second terminal, and a third terminal, the control terminal of the fifth switch coupled to the third terminal of the fourth switch, the second terminal of the fifth switch coupled to a second power supply, and the third terminal of the fifth switch coupled to a second terminal of the third switch of the output switch to define a first output node.

7. The circuit of claim 6, wherein the feedback switch includes an input terminal coupled to a third power supply.

8. The circuit of claim 6, further comprising:
a second output switch including a sixth switch and a seventh switch, the sixth switch and the seventh switch both having a control terminal, a second terminal, and a third terminal, the control terminal of the sixth switch coupled to the charge node, the control terminal of the seventh switch coupled to the third terminal of the fourth switch, the second terminal of the sixth switch coupled to the second terminal of the seventh switch to define a second output node, the third terminal of the sixth switch coupled to a third terminal of the third switch, and the third terminal of the seventh switch coupled to the first power supply.

9. The circuit of claim 8, wherein a low voltage of the second output node is lower than a low voltage of the first output node.

10. The circuit of claim 8, further comprising:
a second input switch including:
an eighth switch having a first terminal and a second terminal, the first terminal coupled to receive a second input signal; and
a ninth switch having a first terminal and a second terminal, the first terminal of the ninth switch coupled to the second terminal of the eighth switch to define a second feedback node;
a third output switch including a tenth switch having a control terminal coupled to the second terminal of the ninth switch to define a second charge node; and
a second feedback switch having an output terminal and a control terminal, the output terminal of the second feedback switch coupled to the second feedback node, the control terminal coupled to the second charge node, the second feedback switch configured to charge the second feedback node responsive to the voltage level at the second charge node.

11. The circuit of claim 10, wherein the eighth switch and the ninth switch have a control terminal, the control terminals of the eighth switch and the ninth switches both coupled to the second output node.

12. The circuit of claim 10, further comprising:
a third input switch including:
an eleventh switch having a first terminal and a second terminal, the first terminal of the eleventh switch coupled to receive a third input signal; and
a twelfth switch having a first terminal, the first terminal of the twelfth switch coupled to the second terminal of the eleventh switch to define a third feedback node.

13. The circuit of claim 12, wherein each of the eleventh switch and the twelfth switch has a control terminal, the control terminals of the eleventh switch and the twelfth switch both coupled to the second output node.

14. The circuit of claim 1, wherein the switches are n-type metal-oxide-semiconductor (NMOS) transistors.

15. The circuit of claim 1, further comprising:
a display including a plurality of display elements;
a processor that is configured to communicate with the display, the processor being configured to process image data; and
a memory device that is configured to communicate with the processor.

16. The circuit of claim 15, further comprising:
a driver circuit configured to send at least one signal to the display; and
a controller configured to send at least a portion of the image data to the driver circuit.

17. The circuit of claim 15, further comprising:
an image source module configured to send the image data to the processor, wherein the image source module comprises at least one of a receiver, transceiver, and transmitter.

18. The circuit of claim 15, further comprising:
an input device configured to receive input data and to communicate the input data to the processor.

19. A circuit for reducing leakage at a floating node, comprising:
means for charging an internal node;
means for floating the internal node;
means for providing feedback from the internal node to a feedback switch; and
means for biasing a feedback node coupled to the feedback switch.

20. The circuit of claim 19, wherein the feedback switch is operable to bias the feedback node responsive to a voltage level at the internal node.

21. The circuit of claim 20, wherein the means for charging the internal node includes a switch operable to charge the internal node to the voltage level.

22. A method for reducing leakage at a floating node, comprising:
charging a first internal node;
floating the first internal node;
providing feedback from the first internal node to a feedback switch; and
biasing a feedback node coupled to the feedback switch.

23. The method of claim 22, further comprising:
providing feedback from the first internal node to a switch coupled to a first power supply;
biasing a second internal node to a first voltage level associated with the first power supply;
biasing a first output node to a second voltage level associated with a second power supply; and
biasing a second output node to the first voltage level.

24. The method of claim 23, wherein the first voltage level is lower than the second voltage level.
